(19) United States
(12) Patent Application Publication
(10) Pub. No.: US 2014/0176159 A1
(43) Pub. Date: Jun. 26, 2014

(54) INDUCTIVE TOUCH KEY SWITCH SYSTEM INCLUDING A DEFLECTION TRANSLATION MECHANISM

(71) Applicants: Sorin Pintiliuc, Hoffman Estates, IL (US); Tony Dmytriw, Dekalb, IL (US); Robert Alvord, Elmwood Park, IL (US)

(72) Inventors: Sorin Pintiliuc, Hoffman Estates, IL (US); Tony Dmytriw, Dekalb, IL (US); Robert Alvord, Elmwood Park, IL (US)

(21) Appl. No.: 14/122,771

(22) PCT Filed: May 29, 2012
(86) PCT No.: PCT/US2012/039828

§ 371 Date: Mar. 3, 2014

Related U.S. Application Data
(60) Provisional application No. 61/490,963, filed on May 27, 2011.

(51) Int. Cl. H03K 17/965; G01R 27/26; H01H 11/00; H03K 17/975

(52) U.S. Cl. CPC H03K 17/965; H03K 17/975; G01R 27/2611; H01H 11/00
USPC 324/655; 200/600; 29/622

(57) ABSTRACT

A key switch assembly is provided wherein a spacer is used to isolate the key switch sensing circuit from the front panel of the device. A button assembly is provided to translate a deflection of the front panel of the device to a target coupled to a sensor of the sensing circuit.

### TECHNICAL FIELD

The instant invention relates to an inductive touch key switch assembly, and more particularly, to an inductive touch key switch system that improves circuit board isolation through the use of a deflection translation mechanism.

Generally, inductive touch key switches and circuits are known. For example, referring now to FIG. 1, MICROCHIP TECHNOLOGY INC. (“MICROCHIP”) of Chandler, Ariz. produces and sells an inductive touch (“touch through metal”) system under the name Inductive mTouch™ and has published an inductive touch key switch assembly design 10 (the “MICROCHIP Design”) that uses a magnetic coupling between a target 12 (made from either solid metal or from a plastic/metal foil combination) and a variable reactance sensor, which in the present case is an inductive sensor or sensor coil 14, separated from one another by a spacer layer 16. Alternately, the metal of the front panel 18 disposed over coil 14 acts as the target 12. The spacer layer 16, which typically has a thickness of between 0.3-0.5 mm, defines a cavity or pocket 17 into which the target 12 can flex when pressed, thus changing the proximity to, and the field around, the sensor coil 14, which is mounted to, printed on and/or etched into a printed circuit board PCB 19. More particularly, when a user presses a key on the front panel 18 (which may be printed on the front panel, only), the front panel 18 deflects, thus moving the metal front panel and/or target 12 closer to the sensor coil 14 etched onto the underlying PCB 19. The inductance of the sensor coil 14 is altered (i.e., by increasing or decreasing the amount of eddy currents in the target), and this inductive change is detected and interpreted by the system as a key press. The front panel 18, also called the top key switch layer or fascia, can be the outermost skin of the product or domestic appliance of which the keyboard is a part.

In accordance with the MICROCHIP Design, a microcontroller is provided to periodically poll various sensors by measuring the impedance of a sensing coil. If the impedance of the sensing coil has changed, then the microcontroller determines if the shift in impedance is sufficient to qualify as a user's press. Such a system is described in U.S. Patent Application Publication Nos. 2010/0090716 and 2010/0090717, those applications being incorporated herein by reference in their entireties for all that they teach.

In a system made in accordance with the MICROCHIP Design, a larger deflection of the solid metal target 12 equates to a larger change in impedance at the sensor coil 14. However, in many applications, the outer material of a key switch (the fascia) is made from a relatively thick piece of stainless steel, for example, 0.032-0.036 inches thick. This creates a problem, in that, the thicker the metal used, the greater is the force required to cause enough deflection to be realized as a key press. To date, expensive technologies utilizing ultrasonic reflections and/or expensive machining/etching of the metal to create local thinner spots in the metal fascia have been used to solve this problem.

What is needed is an inductive touch key switch system in which it is possible to detect impedance changes resulting from much smaller deflections in the metal being touched. What is further needed is an inductive touch key switch system that permits the use of thicker metals, without the need for expensive machining or etching operations.

Additionally, certain problems can arise when using an inductive touch system, as described in connection with FIG. 1. For example, if the front panel of the appliance has holes (i.e., for LEDs or the like), there is a chance that liquids (i.e., water, cleaning liquids, etc.) from outside of the appliance will reach the PCB and damage it. Additionally, some isolation between the sensing circuitry and the user contacted metal parts may be desirable. For non-isolated (AC-line connected) power supplies, a concern is spacing between sensing circuitry and a metal panel that users can touch.

What is further needed is a key switch assembly that can isolate the sensing circuitry from user contacted metal parts and/or external contaminants.

### DISCLOSURE OF THE INVENTION

It is accordingly an object of this invention to provide an inductive touch key switch and circuit that overcomes the disadvantages of the prior art. In one embodiment of the invention, an inductive touch key switch assembly is produced that produces a metal movement that is larger in area relative to a sensor coil than the deflection on the front panel or faceplate of the appliance. More particularly, a key switch assembly is provided wherein a spacer is used to isolate the key switch sensing circuit from the front panel of the device. A button assembly is provided to translate a deflection of the front panel of the device to a target coupled to a sensor of the sensing circuit.

Although the invention is illustrated and described herein as embodied in an an inductive touch key switch system including a deflection translation mechanism, it is nevertheless not intended to be limited to the details shown, since various modifications and structural changes may be made therein without departing from the spirit of the invention and within the scope and range of equivalents of the claims.

The construction of the invention, however, together with the additional objects and advantages thereof will be best understood from the following description of the specific embodiments when read in connection with the accompanying drawings.

### BRIEF DESCRIPTION OF THE DRAWINGS

The present invention is illustrated by way of example, and not by way of limitation, in the figures of the accompanying drawings, in which like reference numerals refer to similar elements and in which:

FIG. 1 is a cross-sectional view of an inductive touch sensor assembly in accordance with the prior art;

FIG. 2 is a cross-sectional view of an inductive touch sensor assembly in accordance with one particular embodiment of the present invention;

FIG. 3 is a cross-sectional view of the inductive touch sensor assembly of FIG. 2, illustrating the displacement of the button assembly and target due to a finger press on the front panel of the appliance;

FIG. 4 is a front perspective view of a metal door panel of an appliance, useful in describing the instant invention.

FIGS. 5A and 5B are perspective views of a light guide useful with one particular embodiment of the present invention.

FIG. 6A is a front perspective view of a spacer part in accordance with one particular embodiment of the invention;

FIG. 6B is a rear perspective view of a spacer part useful in one particular embodiment of the invention;

FIG. 7A is a front perspective view of a button for use with one particular embodiment of the instant invention;

FIG. 7B is a perspective view of a metal target for use with one particular embodiment of the instant invention;

FIGS. 7C and 7D are perspective views from the bottom and top, respectively, of one particular embodiment of a combined button and target, in accordance with one particular embodiment of the invention;

FIG. 8 is a perspective view of the rear face of a metal panel having a light guide engaged therewith;

FIG. 9 is a perspective view of the rear face of a metal panel having a light guide and double-sided tape disposed thereon;

FIG. 10 is a perspective view of the rear face of a metal panel having a spacer part aligned over a light guide engaged with the metal panel;

FIG. 11 is a perspective view of the rear face of a metal panel having a spacer part aligned over a light guide engaged with the metal panel and having buttons engaged with spacer part;

FIG. 12 is a perspective view of the rear face of a metal panel having a spacer part secured to the metal panel and a PCB attached to the rear face of the spacer part; and

FIG. 13 is a perspective view of the door panel in accordance with one particular embodiment of the invention having the final assembly mounted thereon.

### BEST MODE FOR CARRYING OUT THE INVENTION

An inductive touch key switch system, method and circuit are provided herein, which, can be used to amplify and realize a signal by sensing much smaller deflections in the metal being touched than occurs with the MICROCHIP Design. This, in turn, permits the use of thicker metals for the fascia and/or targets in key switch assemblies, which provides the benefits of improving the strength of the materials used and allowing for less force to be applied to the key by the end user.

It should be noted that the circuit, system and method of the instant invention can be used in connection with other inductive touch key switch systems, for example, with the inductive touch key switch system, assembly and circuit described in U.S. patent application Ser. No. 12/696,458 filed on Jan. 29, 2010, and with the inductive touch sensing circuit providing sensitivity compensation described in U.S. patent application Ser. No. 13/070,871, filed on Mar. 24, 2011, or even with the systems disclosed in U.S. Patent Application Publication Nos. 2010/0090716 and 2010/0090717; those applications being incorporated herein by reference in their entireties for all that they teach.

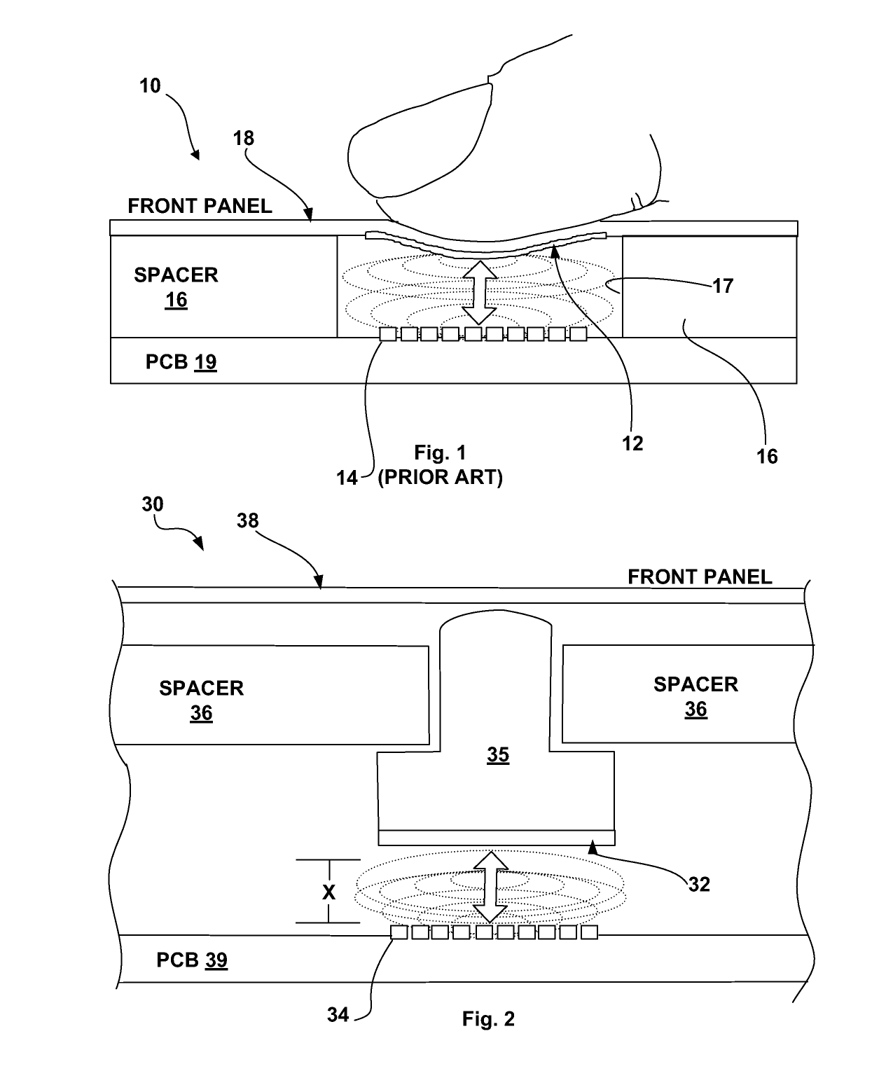

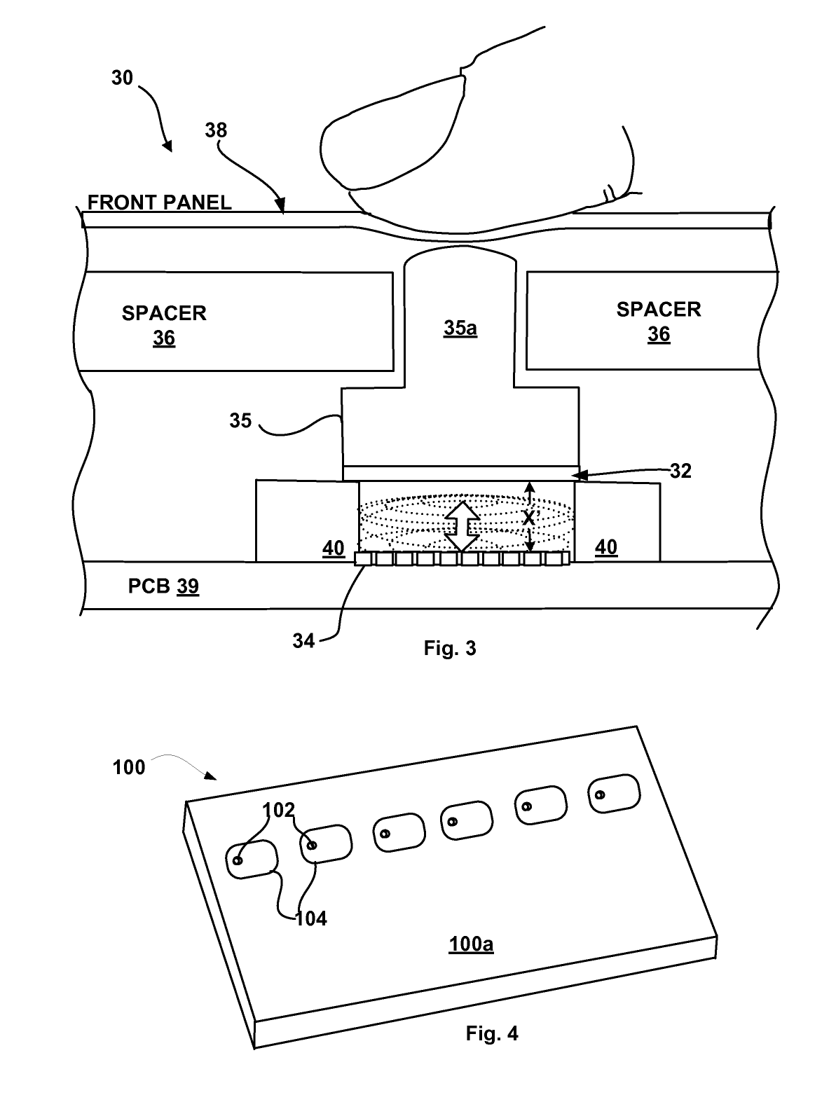

Referring now to FIGS. 2-3, there is shown a key switch assembly 30, made in accordance with one particular embodiment of the present invention. The key switch assembly 30 is an inductive or capacitive key switch assembly, wherein a metal target is aligned with a variable reactance sensor 34 (i.e., a variable inductance or capacitance sensor), such that movement of the target relative to the sensor 34 produces a change in the reactance of the sensor 34 proportional to the deflection on the front panel or faceplate of the appliance. In the present particular embodiment, the sensor 34 is an inductive sensing coil or plate, as desired, as is described in connection with the prior art key switch assembly 10 of FIG. 1.

In accordance with instant embodiment of the invention, the relatively thin (0.3 mm-0.5 mm) spacer of the prior art (16 of FIG. 1), has been replaced by a thicker spacer part 36, which is mounted to the interior of the metal front panel 38 of the appliance. The PCB 39 is mounted to the other side of the spacer part 36. This configuration isolates the PCB from external contaminants, such as water or other liquids, which may enter the key switch assembly 30 through an opening, such as an opening for a light guide or LED. In particular, even if liquids pass through an opening in the front panel 38, the liquid will not proceed to the PCB 39 therebelow. Rather, in the currently described embodiment of the invention, liquids passing through an opening in the front panel 38 of the key switch assembly 30 will drain down to the plastic spacer 36, and will be trapped thereby. The PCB 39 is, thus, protected against liquids.

However, the addition of the thicker spacer 36 additionally increases the distance between the front panel 39 and the sensor 34. Without something more, small movements of the front panel 38 will produce no effect in the sensor 34. As such, in accordance with one particular embodiment of the invention, the inductive touch key switch assembly 30 additionally includes a button or movable piece 35 to transfer the movement from the front panel 38 of the appliance to the sensor 34 on the PCB 39.

The button 35 is interposed between the sensor 34 and the front panel 38, with a portion of the button 35, i.e., neck or shaft 35a, passing through the spacer 36. A metal target 32 is adhered to a bottom surface of the button 35, distal from the front panel 38 of the appliance, such that a surface of the metal target 32 is disposed, at rest, a distance “X” from the sensor 34. In one particular embodiment of the invention, the distance “X” is between 0.3 and 0.7 mm. When a force is applied to the portion of the front panel 38 aligned with the sensor 34 (i.e., a finger push), the deflection is transferred to the button 35 and the distance between the metal target 32 and the sensor 34 decreases (i.e., “X′” of FIG. 3), thus producing a detectible change in the reactance (in the present embodiment, the inductance) of the sensor 34. Only a movement of the button 35 by a few microns should be sufficient to produce a detectible change in inductance.

For purposes of the instant application, it should be noted that the terms “finger press”, “button press”, “key press” and “key push” are used herein to indicate the deflection of a portion of the front panel by a user, which portion includes some form of indicator or indicia that identifies that portion as a “key” that can be pressed to the user. Such indicia can merely be artwork on the front panel in a position aligned with the sensor.

A spring 40 is provided to hold the button 35 off of the PCB 39, and to force button to stay in contact with the inside surface of the front panel 38. Thus, the spring is used to push the button 35 back to its initial position against the spacer, once the force on the front panel 38 (caused by the finger push) has ended. More particularly, upon a return to the initial position of the front panel 38, the spring 40 will similarly return the button 35 to its initial or rest position (i.e., a distance “X” from the sensor 34). The selection of the spring 40 is important for the overall functionality of the key switch assembly 30. The spring 40 should not provide too much force, but should provide enough force to stop the button 35 from moving due to vibrations of the appliance, as well as, to maintain the button against front panel 38. In one particularly preferred embodiment of the invention, the spring is chosen that delivers a spring force of only a few ounces/square inch, at a maximum. Spring 40 can be any type of spring that could perform the functions described herein. In one particular embodiment, the spring 40 is chosen to be a metal spring attached, for example, to the button, or to the top side of the PCB. In another embodiment of the invention, the spring 40 is chosen to be a very soft rubber or foam disc, glued to the metal target 32 of the button 35, or, as shown more particularly in FIG. 3, glued to the PCB 39, over the sensor 34. Alternately, a foam tape can be used as the spring and attached to PCB 39 and/or the bottom surface of the button 35.

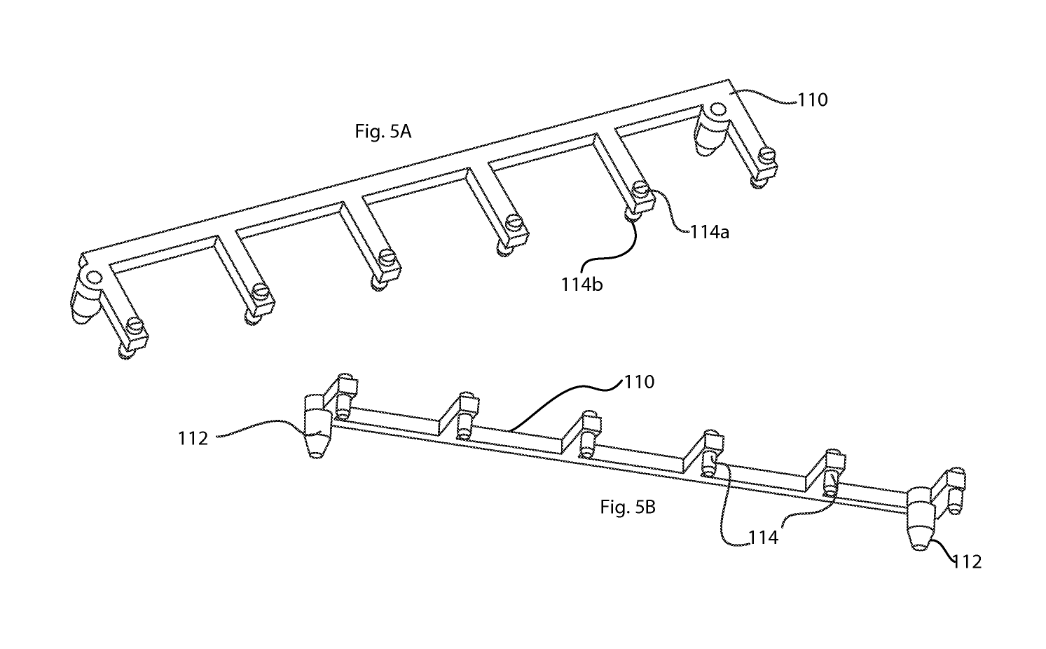

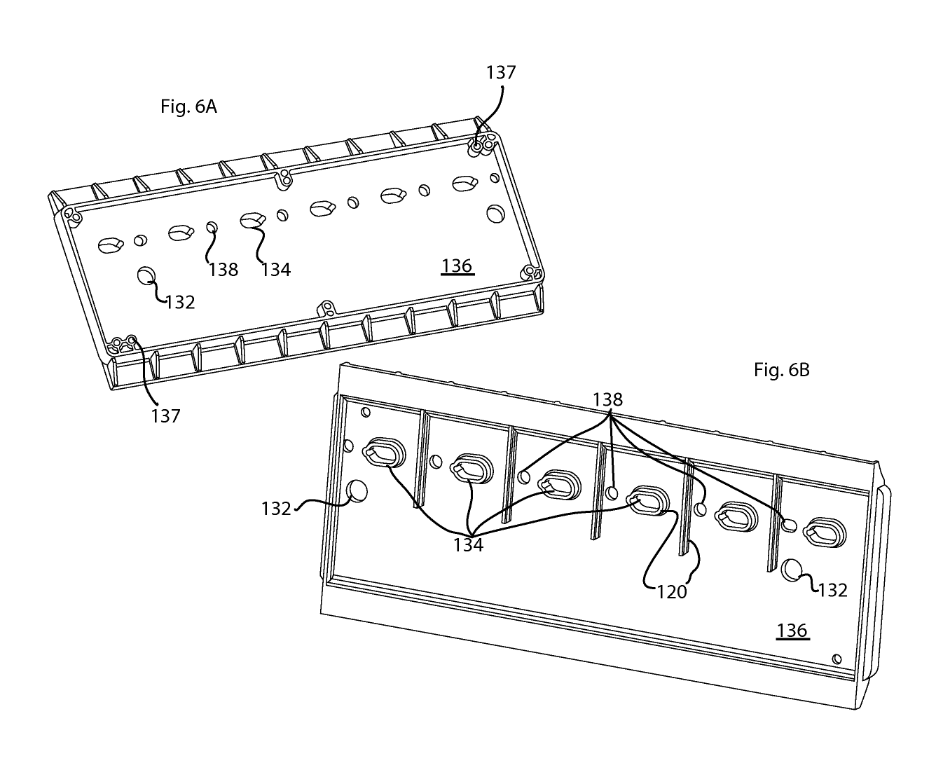

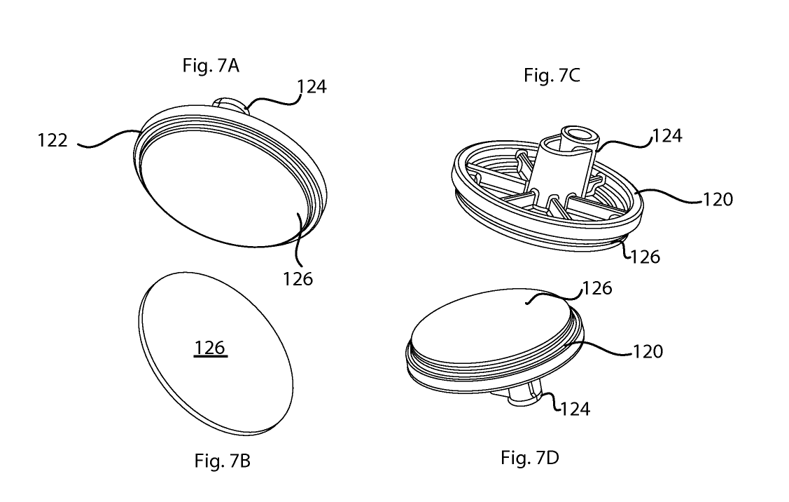

Referring more particularly to FIGS. 4-7D, one embodiment of the present invention will be described in connection with its use in a dishwasher. The use of a dishwasher is an example, only, and is not meant to be limiting. It can be seen that the key switch assembly, described herein, can be adapted for use in any application that uses a button/key operated user interface, without departing from the spirit of the invention. FIG. 4 is a front perspective view of a metal door panel 100 of an appliance, useful in describing the instant invention. More particularly, the front face 100a of the metal door panel 100 includes a plurality of holes 102, therethrough, and may be printed with the artwork indicating a plurality of keys 104. Each of the holes 102 is configured to show an LED or a finger 114 of a light guide, such as a finger 114 of the light guide 110 of FIGS. 5A and 5B, therethrough. Additionally, each of the keys 104 is printed over a touch key switch assembly made in accordance with the instant invention. In one particular embodiment of the invention, the front face 100a is 0.74 mm thick.

A key switch assembly of the instant embodiment is constructed using a spacer part, as described in connection with spacer part 36 of FIGS. 2 and 3, herein. Referring back to FIGS. 4-7D, a spacer part 136 is provided for connection behind the front face 100a of the door panel 100. In the present preferred embodiment, the spacer part 136 is a plastic part that, most preferably has been injection molded, and which provides holes 138 for passing through light from an LED or light guide. In the present particular embodiment, each hole 138 receives a lower projection 114b of a finger 114 of the light guide 110, to maintain a light source in a predetermined relationship between a PCB and the holes in the front face 100a of the front panel 100. In the embodiment shown, the light guide 110 can be maintained in the desired relationship by engaging the light guide pins 112 through the holes 132 on the spacer 136. Additionally, the spacer 136 is provided with holes 134 for receiving the shafts 124 of the buttons 122, therethrough. The shafts 124, and correspondingly, holes 134, may have a circular cross section, if desired, or may have an irregularly shaped or eccentric cross section, as shown, to ensure that the shafts 124 of the buttons 122 are received and maintained in the holes 134 of the spacer 136 in a desired orientation. Each button 122 has a metal target 126 fixed to a bottom surface of the button 122. The metal target 126 can be made as a disc of solid metal, or may be made from plastic coated in a metal foil, or some other configuration. Alternately, a thin sheet of metal or foil could be applied (i.e., painted on, glued, electroplated, etc) directly to the bottom surface of the button 122 to form the metal target 126. In one particular preferred embodiment of the invention, a metal disk 126 is adhered to a bottom surface of the button 122 with double-sided tape, such as very high bond (VHB) double-sided tape.

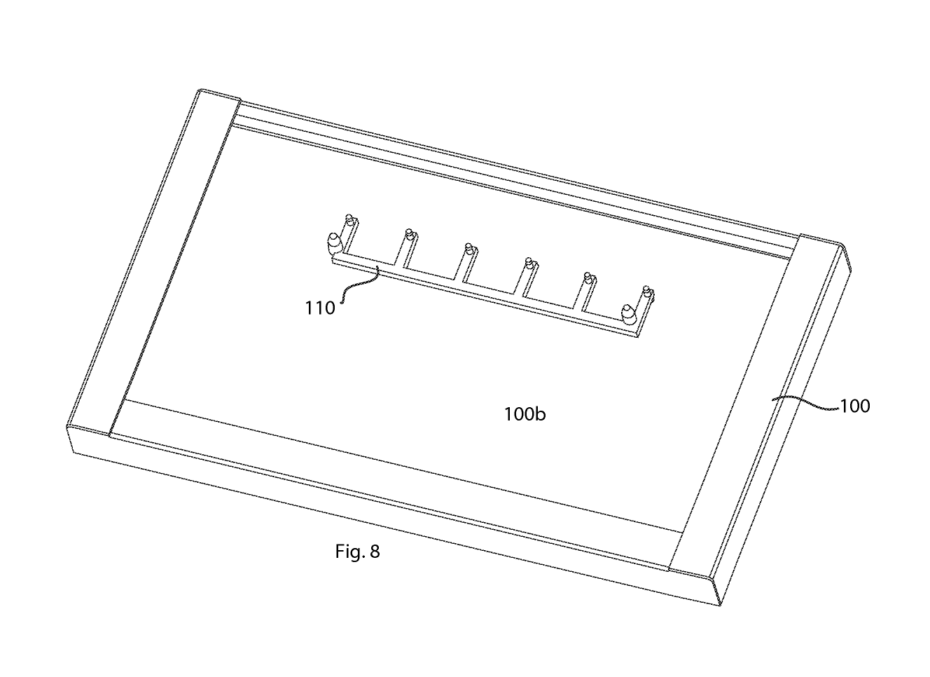

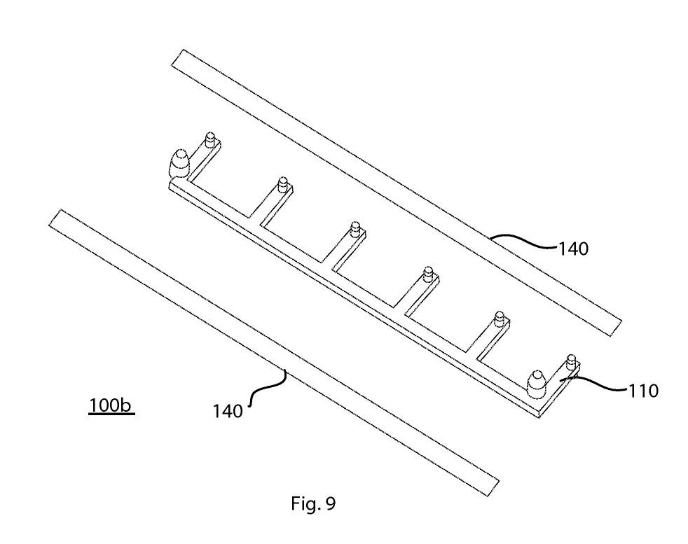

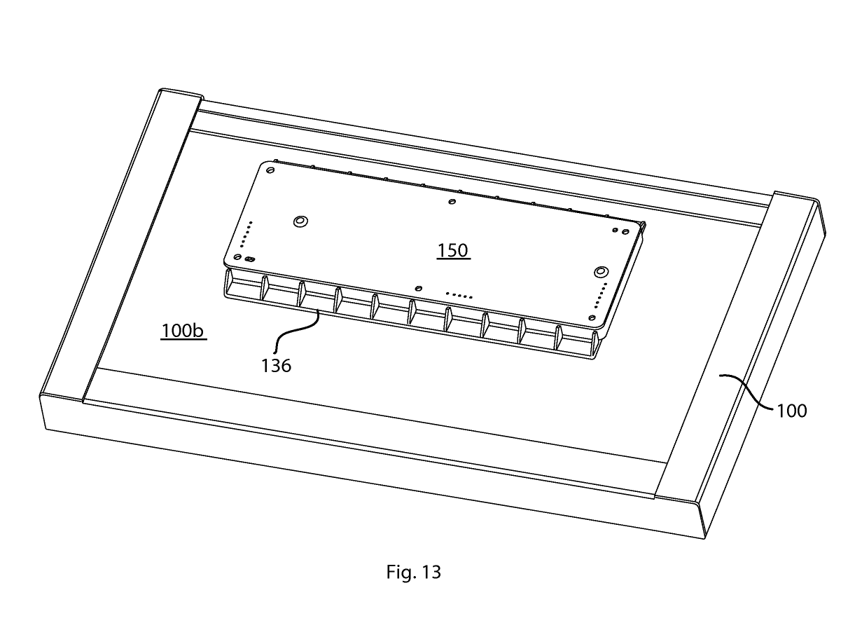

Referring now to FIGS. 4-14, a method of making a “touch through metal” keypad in accordance with one particular embodiment of the present invention will now be described. First, as shown in FIG. 8, the light guide 110 is engaged with the rear face 100b of the door panel 100, such that each of the upper projections 114a of a finger 114 of the light guide 110 are engaged with a hole 102 of the door panel 100.

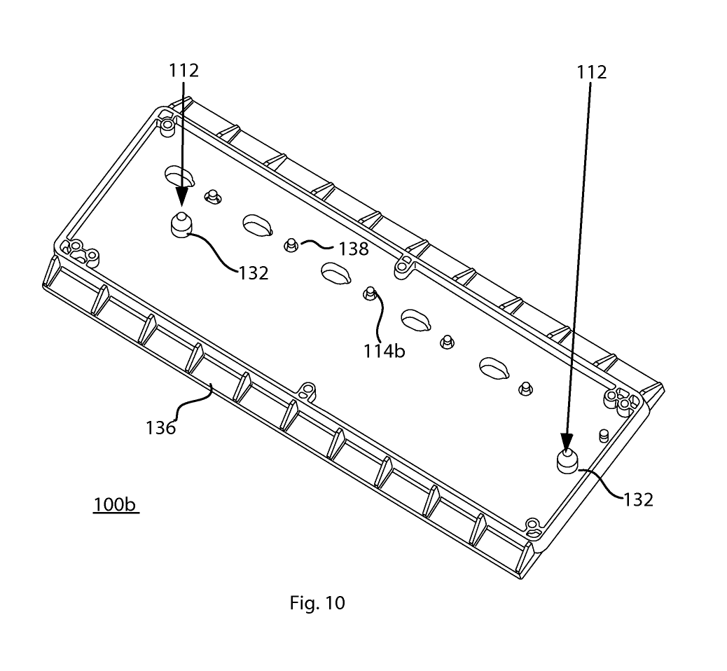

Next, the spacer part 136 is installed over the light guide 110 on the rear face 100b. In one particular embodiment of the invention, a double-sided tape 140, such as a double-sided VHB tape is placed on the rear face 100b, above and below the light guide 110. See, for example, FIG. 9. Alternately, double-sided tape 140 could be placed on the spacer part 136, as desired. The spacer part 136 is applied to the rear face 100b, over the light guide 110, where it is held to the metal door panel 100 by the double-sided tape 140. Molded projections 120 on the underside of the frame help to maintain the frame spaced a predetermined distance from the rear face 100b, and provide room for the light guide 110. As can be seen more particularly from FIG. 10, the light guide pins 112 act as mechanical alignment pins, by ensuring a proper seating and engagement with the holes 132 of the spacer part 136.

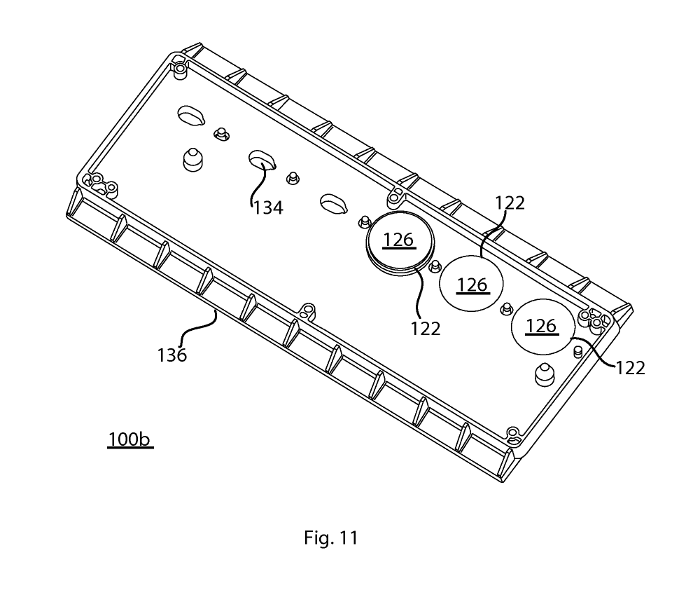

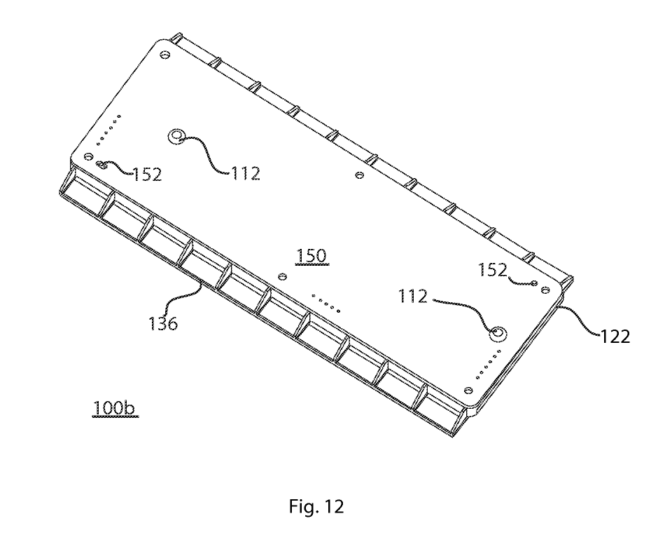

After the spacer part 136 has been adhered to the rear face 100b, the buttons 122 are placed into the spacer by engaging the shaft 124 of each button with a hole 134 on the spacer and dropping the button 122 into place with the metal disc 126 facing outward, as shown in FIG. 11. As described above, after the spacer has been placed and all of the buttons have been dropped into the spacer, the PCB 150 containing the associated LEDs, sensors, sensor drive and detection circuits, etc., is secured to the rear face of the spacer 136. As described more fully in connection with FIG. 3 above, the button assembly of the instant invention includes, not only the button or piece 122 (i.e., 35 of FIG. 3), but also a spring for returning the button to an initial position (40 of FIG. 3). Such a spring may be affixed or adhered directly to the button 122, the target 126 and/or the PCB 150, at the location of the sensor associated with a particular button 122. Regardless of which part the spring is attached to, the completion of the engagement of the PCB 150 to the spacer 136 additionally encloses the springs (40 of FIG. 3) between the sensors of the PCB 150 and the targets 126 of the buttons 122. The PCB 150 includes holes 152 that engage alignment pins 137 located in two of the four corners of the spacer part 136. See, for example, FIG. 12. If desired, the light guide alignment pins 112 can additionally, or alternately, be used to align the PCB relative to the spacer part 136.

Although the invention is illustrated and described herein as embodied in an inductive touch key switch system including a deflection translation mechanism, it is nevertheless not intended to be limited to only these details shown, as various modifications and structural changes may be made therein without departing from the spirit of the invention and within the scope and range of equivalents of the claims.

What is claimed is:

1. A key switch assembly, comprising:
a panel having a front face and a rear face disposed opposite to said front face;
a variable reactance sensor aligned with a portion of the panel;
a spacer disposed between said portion and said sensor;
a movable piece in contact with the rear face of said panel at said portion, said movable piece being displaceable between said portion and said sensor by a deflection of said portion, at least a portion of said movable piece passing through said spacer;
a metal target disposed on a surface of said movable piece proximal to said sensor, the displacement of said movable piece changing the proximity of said metal target to said sensor and, resultantly, changing a reactance of said sensor.

2. The key switch assembly of claim 1, further including a spring disposed between said metal target and said sensor, said spring being configured to bias said movable piece against the rear face of said panel at said portion.

3. The key switch assembly of claim 2, wherein said variable reactance sensor is an inductive sensor.

4. The key switch assembly of claim 2, wherein said spring is a metal coil spring.

5. The key switch assembly of claim 2, wherein said spring is formed as a foam or rubber disc.

6. The key switch assembly of claim 2, wherein said spring is adhered by an adhesive to at least one of said metal target, said movable piece or a printed circuit board (PCB) containing said sensor.

7. The key switch assembly of claim 1, wherein said spacer is formed through injection molding.

8. The key switch assembly of claim 2, wherein:
said panel is a metal panel;
said metal panel includes a first indicia representing a key on said front face;
said variable reactance sensor is aligned with said at least one indicia;
said movable piece in contact with the rear face of said panel is in alignment with said at least one indicia and said movable piece is displaceable between said portion and said sensor by a deflection of said metal panel at said at least one indicia; and
said spring is configured to bias said movable piece against the rear face of said metal panel in alignment with said indicia.

9. The key switch assembly of claim 8, wherein said variable reactance sensor is an inductive sensor.

10. The key switch assembly of claim 8, wherein said variable reactance sensor is a capacitive sensor.

11. The key switch assembly of claim 8, wherein said spring is formed as a foam or rubber disc.

12. The key switch assembly of claim 11, wherein said spring is adhered by an adhesive to at least one of said metal target, said movable piece or a printed circuit board (PCB) containing said sensor.

13. The key switch assembly of claim 8, further comprising:
a plurality of indicia on the front face of said metal panel;
each of said plurality of indicia being aligned with one of a plurality of variable reactance sensors, and separated from said one of a plurality of variable reactance sensors by said spacer;
each of said plurality of indicia being aligned with one of a plurality of movable pieces displaceable relative to its associated sensor by a deflection of said metal panel at said at the associated indicia; and
at least a portion of each movable piece of said plurality of movable pieces passing through said spacer.

14. A method of making a key switch assembly, comprising:
providing a metal panel;
affixing a spacer to said metal panel;
disposing at least one movable button through a portion of said spacer, said movable button including a metal target on a portion thereof; and
affixing a printed circuit board including at least one variable reactance sensor to said spacer, with said at least one metal target being disposed in a predetermined relationship to said at least one sensor.

15. The method of claim 14, wherein a spring is disposed between said at least one movable button and said sensor.

16. The method of claim 15, wherein the spring is adhered to at least one of the printed circuit board, said metal target or said at least one movable button.

17. The method of claim 16, wherein the spring is a foam or rubber disc affixed to said printed circuit board by an adhesive.

18. The method of claim 16, wherein said spring is a foam or rubber disc affixed to said metal target or movable button by an adhesive.

19. The method of claim 16, wherein said spring is a metal spring.

20. The method of claim 16, wherein the spring force constant is selected to resist vibration and to bias said movable button against a portion of said metal panel.
